(19) United States
(12) Patent Application Publication
(10) Pub. No.: US 2025/0366323 A1
(43) Pub. Date: Nov. 27, 2025

(54) DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventors: Zhijun WAN, Shenzhen (CN); Jinchuan LI, Shenzhen (CN)

(73) Assignee: Shenzhen China Star Optoelectronics Semiconductor Display Technology Co., Ltd., Shenzhen (CN)

(21) Appl. No.: 18/789,532

(22) Filed: Jul. 30, 2024

(30) Foreign Application Priority Data
May 21, 2024 (CN) 202410634514.6

(51) Int. Cl. H10K 59/131; H10K 59/122; H10K 59/124; H10K 59/80; H10K 71/16; H10K 71/60

(52) U.S. Cl. CPC H10K 59/131; H10K 59/122; H10K 59/124; H10K 59/871; H10K 71/166; H10K 71/60

(57) ABSTRACT

An embodiment of the present application discloses a display panel and a display panel manufacturing method thereof. The display panel of the embodiment of the present application forms a channel through a light emitting device layer in a buffer region such that material of a cathode can enter a cathode overlap region through the channel and overlap a wiring exposed by a first aperture. When an electron functional layer utilizes an evaporation process, the cathode utilizes an evaporation process or a sputtering process with a smaller evaporation angle and forms the electron functional layer and the cathode by the same mask, material of the cathode and the electron functional layer can extend to the cathode overlap region through the channel due to the configuration of the channel, thereby lower a manufacturing cost for the display panel.

### CROSS REFERENCE TO RELATED APPLICATIONS

The present application claims the priority to Chinese Patent Application No. 202410634514.6, filed on May 21, 2024. The entire disclosures of the above application are incorporated herein by reference.

### FIELD OF INVENTION

The present application relates to a field of display technologies, especially to a display panel and a display panel manufacturing method thereof.

### BACKGROUND OF INVENTION

In the related technology, an organic light emitting diode (OLED) display panel can use the ink jet printing (IJP) process and the evaporation/sputtering process. Due to the limitations in the development of ink for electron transport materials and electron injection materials, the current IJP OLED display panel uses the ink jet printing process to deposit OLED functional layers such as the hole injection layer, hole transport layer, and light emitting layer. The evaporation/sputtering process is used to deposit the electron transport layer, electron injection layer, and cathode, among other OLED functional layers.

The cathode of the OLED display panel needs to be connected to the metal wiring on the driving substrate to enable circuit control of the OLED light emission. Therefore, the film formation region of the cathode needs to be larger than that of the electron transport layer and electron injection layer, allowing the cathode film layer to directly connect with the cathode wiring. The evaporation/sputtering process achieves different film formation regions by changing the aperture design of the mask. Consequently, the aperture size of the mask for forming the cathode film needs to be larger than that for forming the electron transport layer and electron injection layer films. In other words, two masks are required to form the OLED functional layers, significantly increasing the manufacturing cost.

### SUMMARY OF INVENTION

An embodiment of the present application provides a display panel and a display panel manufacturing method thereof, which can lower a manufacturing cost for the display panel.

The embodiment of the present application provides a display panel, comprising a display region and a non-display region located on at least one side of the display region, wherein the non-display region comprises a buffer region and a cathode overlap region located on a side of the buffer region away from the display region, and the display panel comprises:
a thin film transistor structure layer, wherein the thin film transistor structure layer comprises a wiring and an insulation layer covering the wiring, in the cathode overlap region, a first aperture is defined in the insulation layer, and the first aperture exposes the wiring;
a light emitting device layer, wherein the light emitting device layer is disposed on the thin film transistor structure layer, the light emitting device layer comprises an electron functional layer and a cathode covering the electron functional layer and located away from a side of the thin film transistor structure layer; and
a support member, wherein the support member is disposed on the insulation layer and is located on a side of the first aperture away from the buffer region;
wherein in the buffer region, at least one channel is defined in the light emitting device layer, and the channel extends along a direction toward the first aperture and communicates with the first aperture;
wherein in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel.

Optionally, in some embodiments of the present application, the support member is configured to support a mask, the mask comprises a frame and an aperture region, the frame overlaps the support member, the display region and at least one portion of the buffer region is disposed in a region in which the aperture region is located, and the frame shields at least one region of the first aperture; and
the cathode and the electron functional layer is configured to be formed by a same mask.

Optionally, in some embodiments of the present application, the light emitting device layer comprise a planarization layer covering the insulation layer and a pixel definition layer covering the planarization layer, and the electron functional layer covers the pixel definition layer; and
a surface of the insulation layer near the planarization layer serves as a datum surface, a height of a bottom surface of the channel is lower than is located on a surface of the pixel definition layer in the display region away from the thin film transistor structure layer, and the height of the bottom surface of the channel is higher or equal to the datum surface.

Optionally, in some embodiments of the present application, the channel extends through the planarization layer and the pixel definition layer.

Optionally, in some embodiments of the present application, the first aperture is at least one, in an orthographic projection pattern of the display panel, an extension direction of the channel intersects an extension direction of the wiring, and one of the at least one first aperture is disposed correspondingly on an extension direction of the at least one channel.

Optionally, in some embodiments of the present application, in an orthographic projection pattern of the display panel, and the support member is disposed and extends along an extension direction of the wiring.

Optionally, in some embodiments of the present application, a width of the support member is greater than or equal to 10 microns.

Optionally, in some embodiments of the present application, a thickness of the support member is greater than or equal to 4 microns.

Optionally, in some embodiments of the present application, at least one of the planarization layer and the pixel definition layer and at least one portion of the support member are disposed in a same layer and made of same material.

Optionally, in some embodiments of the present application, the support member comprises a first portion, a second portion, and a third portion sequentially stacked on the insulation layer, the first portion and the planarization layer are disposed in a same layer and made of same material, and the second portion and the pixel definition layer are disposed in a same layer and made of same material.

Optionally, in some embodiments of the present application, the electron functional layer is connected to a portion of the wiring in the first aperture through the channel, and the cathode covers the electron functional layer in the first aperture and is connected to an exposed portion of the wiring.

Optionally, in some embodiments of the present application, the electron functional layer comprises at least one of an electron transport layer and an electron injection layer, the light emitting device layer further comprises an anode, a light emitting layer, and a hole functional layer, the anode is disposed on the planarization layer, a second aperture is defined in the pixel definition layer, the second aperture exposes the anode, the hole functional layer and the light emitting layer are disposed sequentially on the anode and located in the second aperture, and the electron functional layer is disposed on the light emitting layer.

Accordingly, the embodiment of the present application further provides a display panel, comprising a display region and a non-display region located on at least one side of the display region, wherein the non-display region comprises a buffer region and a cathode overlap region located on a side of the buffer region away from the display region, and the display panel comprises:
a thin film transistor structure layer, wherein the thin film transistor structure layer comprises a wiring and an insulation layer covering the wiring, in the cathode overlap region, a first aperture is defined in the insulation layer, and the first aperture exposes the wiring;
a light emitting device layer, wherein the light emitting device layer is disposed on the thin film transistor structure layer, the light emitting device layer comprises an electron functional layer and a cathode covering the electron functional layer and located away from a side of the thin film transistor structure layer; and
a support member, wherein the support member is disposed on the insulation layer and is located on a side of the first aperture away from the buffer region;
wherein in the buffer region, at least one channel is defined in the light emitting device layer, and the channel extends along a direction toward the first aperture and communicates with the first aperture;
wherein in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel;
wherein the light emitting device layer comprise a planarization layer covering the insulation layer and a pixel definition layer covering the planarization layer, and the electron functional layer covers the pixel definition layer; and
wherein a surface of the insulation layer near the planarization layer serves as a datum surface, a height of a bottom surface of the channel is lower than is located on a surface of the pixel definition layer in the display region away from the thin film transistor structure layer, and the height of the bottom surface of the channel is higher or equal to the datum surface;
wherein the channel extends through the planarization layer and the pixel definition layer;
wherein the first aperture is at least one, in an orthographic projection pattern of the display panel, an extension direction of the channel intersects an extension direction of the wiring, and one of the at least one first aperture is disposed correspondingly on an extension direction of the at least one channel.

Accordingly, the embodiment of the present application further provides a display panel manufacturing method, wherein a display panel comprises a display region and a non-display region located on at least one side of the display region, wherein the non-display region comprises a buffer region and a cathode overlap region located on a side of the buffer region away from the display region, and the display panel manufacturing method comprises steps as follows:

form an insulative lamination layer and a support member on a thin film transistor structure layer, wherein the thin film transistor structure layer comprises a wiring and an insulation layer covering the wiring, in the cathode overlap region, a first aperture is defined in the insulation layer, and the first aperture exposes the wiring; the support member is disposed on the insulation layer and is located on a side of the first aperture away from the buffer region; at least one channel is formed in a region of the insulative lamination layer corresponding to the buffer region, and the first aperture is located along an extension direction of the channel;
overlapping a mask on the support member, wherein the mask comprises a frame and an aperture region, the frame overlaps the support member, the display region and at least one portion of the buffer region is disposed in a region in which the aperture region is located, and the frame shields at least one region of the first aperture; and
sequentially forming an electron functional layer and a cathode on the insulative lamination layer by the mask, wherein a film formation range of the cathode is greater than a film formation range of the electron functional layer, in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel.

The display panel of the embodiment of the present application forms the channel in light emitting device layer through the buffer region such that material of the cathode can enter the cathode overlap region through the channel and overlap the wiring exposed by the first aperture.

It can be understood that when an electron functional layer utilizes an evaporation process, the cathode utilizes an evaporation process or a sputtering process with a smaller evaporation angle and forms the electron functional layer and the cathode by the same mask, material of the cathode and the electron functional layer can extend to the cathode overlap region through the channel due to the configuration of the channel. Also, the cathode utilizes the sputtering process or utilizes the smaller evaporation angle to implement evaporation such that a film formation range of the cathode is greater than a film formation range of the electron functional layer to make the cathode able to overlap the wiring to implement light emission of the light emitting device layer, thereby lower a manufacturing cost for the display panel.

### DESCRIPTION OF DRAWINGS

FIG. 1 is a schematic view of an orthographic projection of a display panel provided by an embodiment of the present application;

FIG. 2 is an enlarged view of a Q portion in FIG. 1;

FIG. 3 is a cross-sectional schematic view along a line CC in FIG. 2;

FIG. 4 is a schematic view of a partial orthographic projection of a display panel provided by another embodiment of the present application;

FIG. 5 is a schematic view of a curvature of a cathode and an electron functional layer with curves of different distances corresponding to different film thicknesses;

FIG. 6 is a schematic view of a partial orthographic projection of a display panel provided by still another embodiment of the present application;

FIG. 7 is a cross-sectional schematic view along a line SS in FIG. 6;

FIG. 8 is a schematic cross-sectional structural view of a display panel provided by still another embodiment of the present application;

FIG. 9 is a schematic structural view of a step B2 of a display panel manufacturing method of the embodiment of the present application; and

FIG. 10 is a schematic structural view of a step B3 of the display panel manufacturing method of the embodiment of the present application.

### DETAILED DESCRIPTION OF PREFERRED EMBODIMENTS

The following will provide a clear and complete description of the technical solution in the embodiment of the present application in conjunction with the accompanying drawings. It is evident that the described embodiment is merely a part of the embodiments of the present application and not all of them. Based on the embodiments of the present application, all other embodiments obtained by those skilled in the art without making inventive efforts also fall within the scope of protection of the present application. Furthermore, it should be understood that the specific implementations described here are only for illustration and explanation of the present application and are not intended to limit the present application. In the present application, unless stated otherwise, directional terms such as “upper” and “lower” usually refer to the actual usage or working state of the device, specifically the direction shown in the drawings; “inner” and “outer” refer to the outline of the device; terms such as “first,” “second,” and “third” are merely used for labeling purposes without imposing numerical requirements or establishing sequences.

The embodiment of the present application provides a display panel and a display panel manufacturing method, which will be described in detail below. It should be noted that the order of description of the following embodiments does not serve as a limitation on the preferential order of the embodiments.

With reference to FIGS. 1 to 3, the embodiment of the present application provides a display panel 100 comprising a display region AA and a non-display region NA located on at least one side of the display region AA. The non-display region NA comprises a buffer region NA1 and a cathode overlap region NA2 located on a side of the buffer region NA1 away from the display region AA.

The display panel 100 comprises a thin film transistor structure layer 10, a light emitting device layer 20, and a support member 30.

The thin film transistor structure layer 10 comprises a wiring 11 and an insulation layer 12 covering the wiring 11. In the cathode overlap region NA2, a first aperture k1 is defined in the insulation layer 12, and the first aperture k1 exposes the wiring 11.

The light emitting device layer 20 is disposed on the thin film transistor structure layer 10. The light emitting device layer 20 comprises an electron functional layer 21 and a cathode 22 disposed on a side of the electron functional layer 21 away from the thin film transistor structure layer 10.

The support member 30 is disposed on the insulation layer 12 and is located on a side of the first aperture k1 away from the buffer region NA1.

In the buffer region NA1, at least one channel td is defined in the light emitting device layer 20. The first aperture k1 is located along an extension direction of the channel td. Namely, the channel td extends along a direction toward the first aperture k1 and is connected to the first aperture k1.

In the non-display region NA of an orthographic projection pattern of the display panel 100, a boundary of the cathode 22 extends beyond a boundary of the electron functional layer 21. The electron functional layer 21 at least covers the display region AA and the buffer region NA1. The cathode 22 covers the display region AA and the buffer region NA1 and is connected to the wiring 11 in the first aperture k1 through the channel td.

The display panel 100 of the embodiment of the present application forms the channel td through the light emitting device layer 20 in the buffer region NA1 such that material of the cathode 22 can enter the cathode overlap region NA2 through the channel td and overlap the wiring 11 exposed by the first aperture k1.

It can be understood that the support member 30 is configured to support a mask. The mask comprises a frame and an aperture. The frame overlaps the support member 30. The display region AA and at least one portion of the buffer region NA1 are defined in the aperture region. The frame shields at least region of the first aperture k1. The cathode 22 and the electron functional layer 21 are configured to be formed by the same mask.

The at least region of the first aperture k1 is shielded by the mask, a diffusion phenomenon of material in the process is utilized to make the cathode material and the electron functional layer material extend through the channel td and enter the first aperture k1 of the cathode overlap region NA2. A portion of the material entering the cathode overlap region NA2 is a diffusion portion.

When the electron functional layer 21 utilizes an evaporation process, the cathode 22 utilizes a sputtering process or an evaporation process with a smaller evaporation angle and forms the electron functional layer 21 and the cathode 22 under the same mask. Because of configuration of the channel td, material of the cathode 22 and the electron functional layer 21 can extend to the cathode overlap region NA2 through the channel td. Also, the cathode 22 utilizes the sputtering process or the smaller evaporation angle to implement evaporation such that a film formation range of the cathode 22 is greater than a film formation range of the electron functional layer 21. Therefore, the cathode 22 can overlap the wiring 11 to implement light emission of the light emitting device layer to lower a manufacturing cost for the display panel.

Optionally, a frame of the mask can completely shield the first aperture k1, and can also shield the first aperture k1.

Optionally, the non-display region NA is disposed on a side of the display region AA, the wiring 11 is only disposed on a side of the display region AA. In some embodiments, the non-display region NA is disposed on a periphery of the display region AA, the wiring 11 surrounds the periphery of the display region AA to form a closed loop structure. In some embodiments, the non-display region NA is disposed on adjacent two or three sides of the display region AA, and the wiring 11 is disposed on the periphery of the display region AA and is folding-line-like.

Optionally, the electron functional layer 21 is also connected to a portion of the wiring 11 through the first aperture k1. Namely, the electron functional layer 21 is connected to a portion of the wiring 11 near the buffer region NA1. The cathode 22 covers the electron functional layer 21 located in the first aperture k1 and is connected to an exposed portion of the wiring 11. Such configuration can reduce a width of the non-display region NA. Furthermore, the electron functional layer 21 first covers a sidewall of the first aperture k1 to perform an effect of lowering a slope of the first aperture k1, thereby improving continuity of the cathode 22 covering the first aperture k1 and lowering a risk of broken lines.

In an embodiment, the electron functional layer 21 does not overlap the wiring 11 in the first aperture k1, thereby increasing an area of the cathode 22 overlapping the wiring 11 to further improve connection stability.

Optionally, the thin film transistor structure layer 10 can comprise at least one of a top gate type thin film transistor, a bottom gate type thin film transistor, a dual-gate type thin film transistor, and a vertical type thin film transistor. The present embodiment will be described with one framework of top gate type thin film transistor, but has not limit thereto.

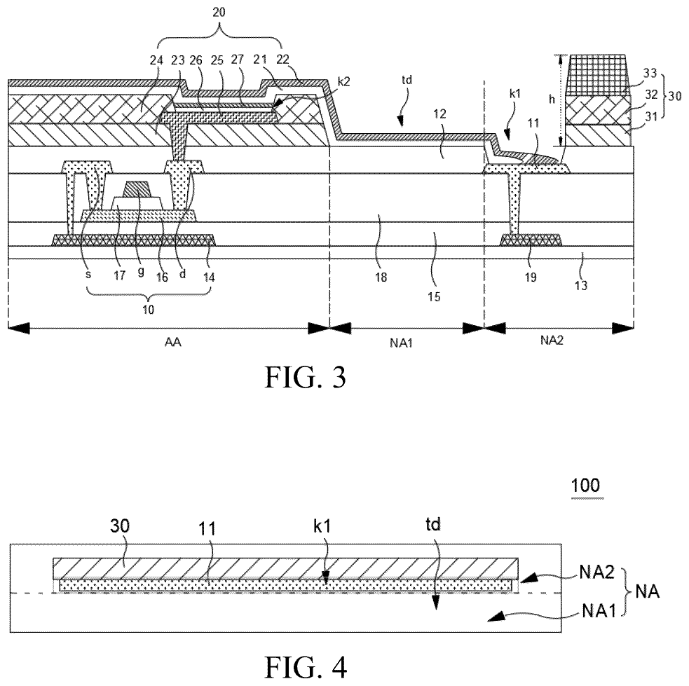

With reference to FIG. 3, in an embodiment, the thin film transistor structure layer 10 comprises an underlay 13, a light shielding layer 14, a buffer layer 15, an active layer 16, a gate insulation layer 17, a gate electrode g, an interlayer dielectric layer 18, a source electrode s, and a drain electrode d that are sequentially stacked on one another. The wiring 11 and the source electrode s are disposed in the same layer, and are disposed on the interlayer dielectric layer 18. The insulation layer 12 also covers the source electrode s, the drain electrode d, and the interlayer dielectric layer 18.

Optionally, the thin film transistor structure layer 10 further comprises a signal access line 19 in the same layer with and spaced from the light shielding layer 14. The wiring 11 is connected to the signal access line 19 through a via hole. The signal access line 19 is set to receive a cathode signal.

Optionally, in an embodiment, the light emitting device layer 20 comprises a planarization layer 23 covering the insulation layer 12 and a pixel definition layer 24 covering the planarization layer 23. The electron functional layer 21 covers the pixel definition layer 24.

The light emitting device layer 20 further comprises an anode 25, a hole functional layer 26 and a light emitting layer 27. The anode 25 is disposed on the planarization layer 23. A second aperture k2 is defined in the pixel definition layer 24, and the second aperture k2 exposes the anode 25. The hole functional layer 26 and the light emitting layer 27 are sequentially disposed on the anode 25 and located in the second aperture k2. The electron functional layer 21 is disposed on the light emitting layer 27. The anode 25 is connected to the drain electrode d of the thin film transistor through a via hole.

Optionally, the electron functional layer 21 comprises at least one of an electron transport layer and an electron injection layer, the hole functional layer 26 comprises at least one of a hole transport layer and a hole injection layer. In the present embodiment, the electron functional layer 21 comprises the electron transport layer and the electron injection layer sequentially stacked on the light emitting layer 27. The hole functional layer 26 comprises the hole injection layer and the hole transport layer sequentially stacked on the anode 25.

In some embodiments, the hole functional layer 26 can further comprise a light emitting auxiliary layer/an electron barrier layer, and the electron functional layer 21 can further comprise a hole barrier layer.

Optionally, a surface of the insulation layer 12 near the planarization layer 23 serves as a datum surface, a height of the bottom surface of the channel td is lower than a surface of the pixel definition layer 24 away from the thin film transistor structure layer 10 located in the display region AA. Also, the height of the bottom surface of the channel td is higher or equal to the datum surface.

For example, in the buffer region NA1, a hollow opening exposing the insulation layer 12 is defined in the planarization layer 23. The pixel definition layer 24 covers the hollow opening to form a recessed portion that is lower than the display region AA. A recess (the channel td) of the recessed portion extends along a direction toward the first aperture k1 and communicates with the first aperture k1 such that material can pass through the recess and enter the first aperture k1 in the cathode overlap region NA2.

For another example, in the buffer region NA1, the hollow opening exposing the planarization layer 23 is defined in the pixel definition layer 24. Top surfaces of the hollow opening and the planarization layer 23 for the recess (the channel td). The recess (the channel td) of the recessed portion extends along a direction toward the first aperture k1 and communicates with the first aperture k1. Then, the material can enter the first aperture k1 of the cathode overlap region NA2 through the recess.

For another example, in an embodiment, the channel td extends through the planarization layer 23 and the pixel definition layer 24. Namely, the bottom surface of the channel td is equal to the above datum surface.

In the orthographic projection pattern of the display panel 100, the extension direction of the channel td y intersects an extension direction of the wiring 11. An extension direction of the channel td is a direction from the buffer region NA1 to the cathode overlap region NA2.

The channel td extending through the planarization layer 23 and the pixel definition layer 24 deepens the channel td such that a barrier at a front end of the first aperture k1 is decreased to facilitate more material entering the first aperture k1, thereby increasing an overlap area and an overlap thickness of the cathode 22 with the wiring 11 to raise stability of the cathode 22 overlapping the wiring 11.

It can be understood that the barrier on the front end of the first aperture k1 refers to a member obstructing the cathode material from entering the first aperture k1, for example, the portion of the planarization layer 23 and the pixel definition layer 24 located near and facing the first aperture k1.

The less the barrier on the front end of the first aperture k1 is, the more the material entering the first aperture k1 is. Furthermore, the deeper a depth of the channel td is, namely, the lower the barrier on the front end of the first aperture k1 is, the more the material enters the first aperture k1, thereby increasing stability of overlapping the wiring 11.

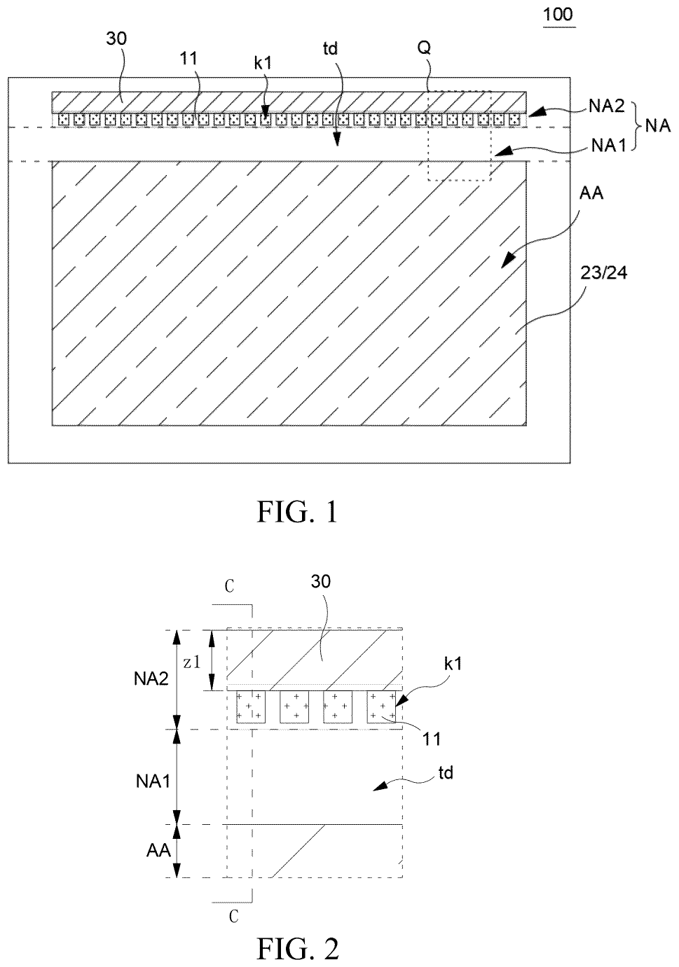

With reference to FIGS. 1 and 2, optionally, in the orthographic projection pattern of the display panel 100, an extension direction of an end portion of the channel td is parallel to the extension direction of the wiring 11. The end portion of the channel td extends toward an edge of the display panel 100 to form a sheet-like channel td. Along a long side direction of the display panel 100, a length of the channel td is equal to or greater than a length of the wiring 11 such that the front end of the first aperture k1 has no barrier obstructing the cathode material from extending, thereby increasing a success rate of the material entering the first aperture k1.

Optionally, in the orthographic projection pattern of the display panel 100, an extension direction of a side portion of the channel td is parallel to a short side direction of the display panel 100. The extension direction of the side portion of the channel td is perpendicular to the extension direction of the wiring 11 such that the material enters the first aperture k1 by the same distance, thereby preventing a partial region of the cathode 22 not overlapping the wiring 11.

Optionally, with reference to FIG. 2, in the orthographic projection pattern of the display panel 100, the first aperture k1 is at least one. In the orthographic projection pattern of the display panel 100, the extension direction of the side portion of the channel td intersects the extension direction of the wiring 11, one of the first aperture k1 is disposed correspondingly on the extension direction of the side portion of the channel td.

A plurality of the first apertures k1 are disposed at intervals such that the insulation layer 12 covers the wiring 11 at intervals, thereby lowering a risk of the wiring 11 peeling off.

Optionally, with reference to FIG. 4, in an embodiment of the present application, the first aperture k1 is one. In the orthographic projection pattern of the display panel 100, the first aperture k1 extends along the extension direction of the wiring 11, one first aperture k1 is disposed correspondingly on the extension direction of the side portion of one channel td. Utilizing an elongated first aperture k1 to expose the wiring 11 increases an exposed area of the wiring 11 such that the cathode 22 can overlap the wiring 11 more to increase the overlap area.

Optionally, in an embodiment, in the orthographic projection pattern of the display panel 100, the support member 30 extends along the extension direction of the wiring 11. Namely the support member 30 is elongated to improve a supporting ability to the mask.

Optionally, a width z1 of the support member 30 is greater than or equal to 10 microns, for example the width z1 can be 10 microns, 20 microns, 30 microns, 40 microns, 50 microns, 60 microns, 70 microns, 80 microns, 90 microns, 100 microns, 150 microns, 200 microns, 250 microns, 300 microns, 350 microns, or 400 microns.

Optionally, in an embodiment, a width of the support member 30 is also less than or equal to 400 microns.

It can be understood that the smaller the width z1 of the support member 30 is, the smaller the frame width is, the weaker a supporting strength of the support member 30 for the mask is, and the easier an edge of an aperture of the mask deforms. For fulfillment of the requirement of the strength supporting the mask and prevention of a risk of an over large frame width, the width of the support member 30 is selected to be less than or equal to 400 microns.

Optionally, a thickness h of the support member 30 is greater than or equal to 4 microns, for example, the thickness h can be 4 microns, 5 microns, 6 microns, 7 microns, 8 microns, 9 microns, 10 microns, 11 microns, 12 microns, 13 microns, 14 microns, 15 microns, 16 microns, 17 microns, 18 microns, 19 microns, 20 microns, 21 microns, 22 microns, 23 microns, 24 microns, 25 microns, 26 microns, 27 microns, 28 microns, 29 microns, 30 microns, 35 microns, 40 microns, 45 microns, or 50 microns.

It can be understood that the greater the thickness h of the support member 30 is, the greater a distance of the mask from the channel td bottom surface is, the greater a diffusion range of the material entering the cathode overlap region NA2 is, and the greater the success rate and the stability of the cathode 22 overlapping the wiring 11 are.

Optionally, in an embodiment, at least one of the planarization layer 23 and the pixel definition layer 24 and at least one portion of the support member 30 are disposed in a same layer and made of same material. For example, the support member 30 and the planarization layer 23 or the pixel definition layer 24 can be manufactured by the same mask. Also, for example, a portion of the support member 30 and the planarization layer 23 are manufactured by the same mask, and another portion of the support member 30 and the pixel definition layer 24 are manufactured by the same mask.

In an embodiment, the support member 30 can also be manufactured by another film layers different from the planarization layer 23 and the pixel definition layer 24 by using the same mask. Alternatively, a portion of the support member 30 and the planarization layer 23 or the pixel definition layer 24 are manufactured by the same mask, and another portion of the support member 30 and another film layer are manufactured by the same mask.

Optionally, in an embodiment, the support member 30 comprises a first portion 31, a second portion 32, and a third portion 33 sequentially stacked on the insulation layer 12. The first portion 31 and the planarization layer 23 are disposed in a same layer and made of same material. The second portion 32 and the pixel definition layer 24 are disposed in a same layer and made of same material. The third portion 33 and a spacer column are disposed in a same layer and made of same material. Such design can simplify processes.

It should be understood that the electron functional layer 21 of the display panel 100 of the embodiment of the present application can be manufactured by an evaporation process, and the cathode 22 can be manufactured by an evaporation process or a sputtering process. When both are manufactured by an evaporation process, an evaporation angle for manufacturing the cathode 22 is less than an evaporation angle for manufacturing the electron functional layer 21. When the electron functional layer 21 is manufactured by an evaporation process and the cathode 22 is manufactured by a sputtering process, no angle consideration is required but only common processes are needed.

When the electron functional layer 21 and the cathode 22 are both manufactured by an evaporation process, the evaporation angle for manufacturing the cathode 22 is θ. In the channel td region, a distance L2 between the first aperture k1 and the planarization layer 23 and the pixel definition layer 24 in the display region AA is greater than or equal to the thickness h/tan θ of the support member 30, thereby guaranteeing the material passing through the channel td. The present application is described according to an example of the electron functional layer 21 manufactured by the evaporation process and the cathode 22 manufactured by the sputtering process.

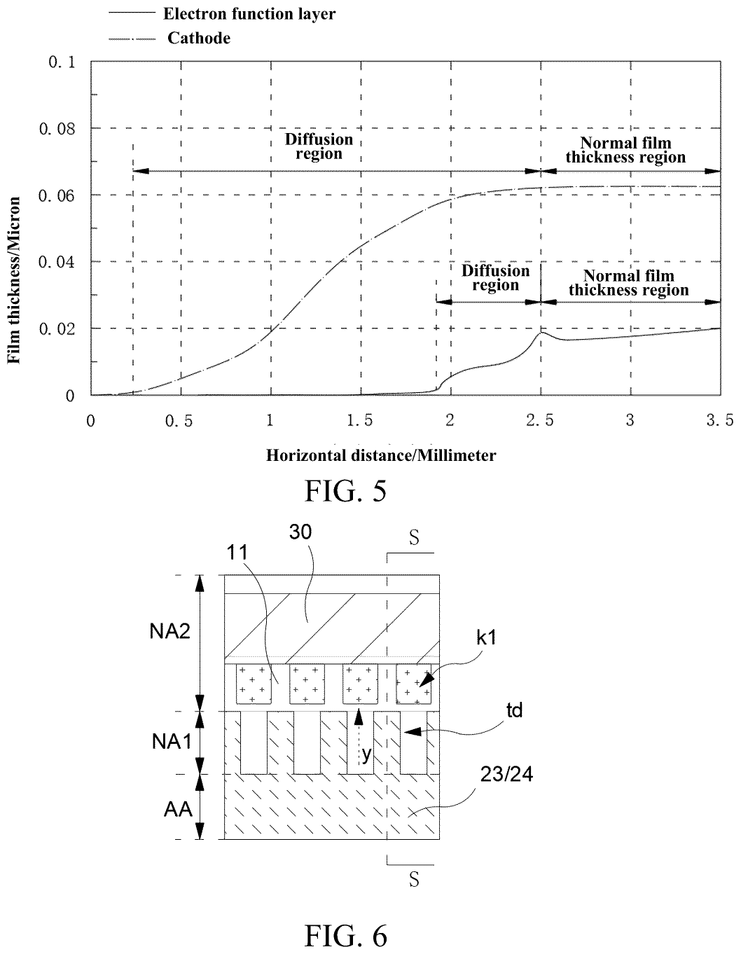

According to difference principles of the film formation of the evaporation process and the film formation of the sputtering process, during the film formation of the sputtering process, a sputtering direction of material particles is random, and film formation of the evaporation process, material particles are limited by the evaporation angle, and therefore when the same mask is used for film formation, a film layer diffusion region of the film formation of the sputtering process would be greater than a film layer diffusion region of the film formation of the evaporation process. Even when a mask with the same aperture pattern is used, a film layer covering region of the cathode 22 is greater than a film layer covering region of the electron functional layer 21, as shown in FIG. 5.

The electron functional layer 21 and the cathode 22 utilizing the same mask allows to dispose only one film formation chamber on a production line for manufacturing the electron functional layer 21 and the cathode 22, thereby saving a film formation chamber and lower the manufacturing cost.

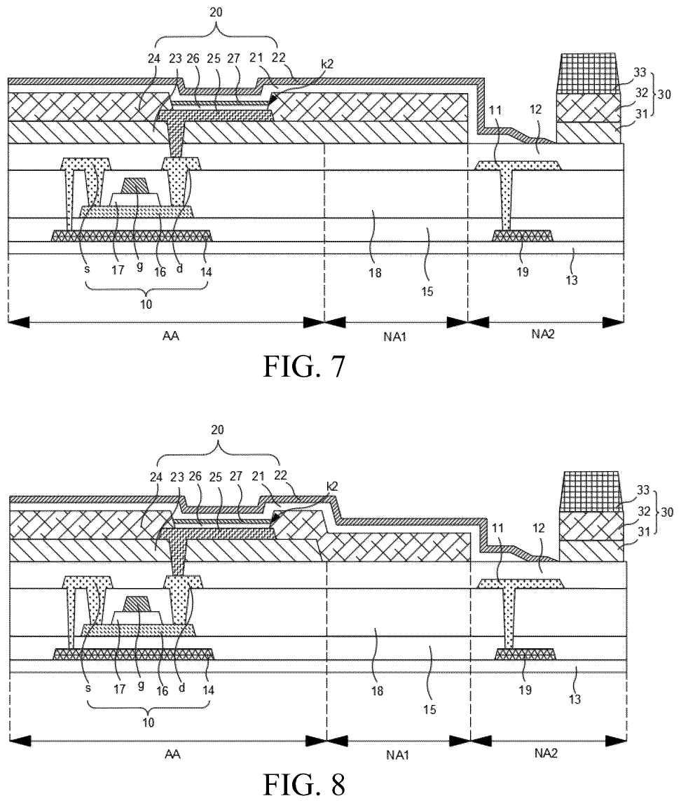

In still another embodiment, with reference to FIGS. 6 and 7, compared to the above embodiment, the channel td is plural, the channels td are arranged at intervals along the extension direction of the wiring 11. The planarization layer 23 and the pixel definition layer 24 extend to the buffer region NA1. The channel td extends through the planarization layer 23 and the pixel definition layer 24.

The first portion 31 of the support member 30 and the planarization layer 23 have the same material and are formed by the same mask. The second portion 32 and the pixel definition layer 24 have the same material and are formed by the same mask. Second, multiple the channels td are utilized to increase a covering area of the cathode 22, thereby reducing voltage drop of the cathode 22 while increasing adhesion ability of the cathode 22.

In an embodiment, with reference to FIG. 8, one of the planarization layer 23 and the pixel definition layer 24 does not extend in the buffer region NA1, and the other of the planarization layer 23 and the pixel definition layer 24 extends in the buffer region NA1. Second, multiple channels td are utilized to increase the covering area of the cathode 22, thereby reducing voltage drop of the cathode 22 while increasing adhesion ability of the cathode 22. Also, one of the planarization layer 23 and the pixel definition layer 24 entering the buffer region NA1 can reduce a climbing height of the cathode 22, thereby lowering a risk of the broken cathode 22 and increasing integrity and continuity of the cathode 22.

Optionally, the pixel definition layer 24 extends in the buffer region NA1, and the second portion 32 of the support member 30 and the pixel definition layer 24 have the same material and are formed by the same mask.

Accordingly, the embodiment of the present application further provides a display panel manufacturing method. The display panel comprises a display region and a non-display region NA located in at least one side of the display region AA. The non-display region NA comprises a buffer region NA1 and a cathode overlap region NA2 located on the side of the buffer region NA1 away from the display region AA.

The present manufacturing method is configured to manufacture the display panel 100 of the above embodiment. The display panel manufacturing method comprises steps as follows:

A step B1 comprises forming an insulative lamination layer and a support member 30 on the thin film transistor structure layer 10. The thin film transistor structure layer 10 comprises a wiring 11 and an insulation layer 12 covering the wiring 11. In the cathode overlap region NA2, a first aperture k1 is defined in the insulation layer 12, and the first aperture k1 exposes the wiring 11. The support member 30 is disposed on the insulation layer 12 and is located on a side of the first aperture k1 away from the buffer region NA1. at least one the channel td is formed in a region of the insulative lamination layer corresponding to the buffer region NA1, the first aperture k1 is located along an extension direction of the channel td.

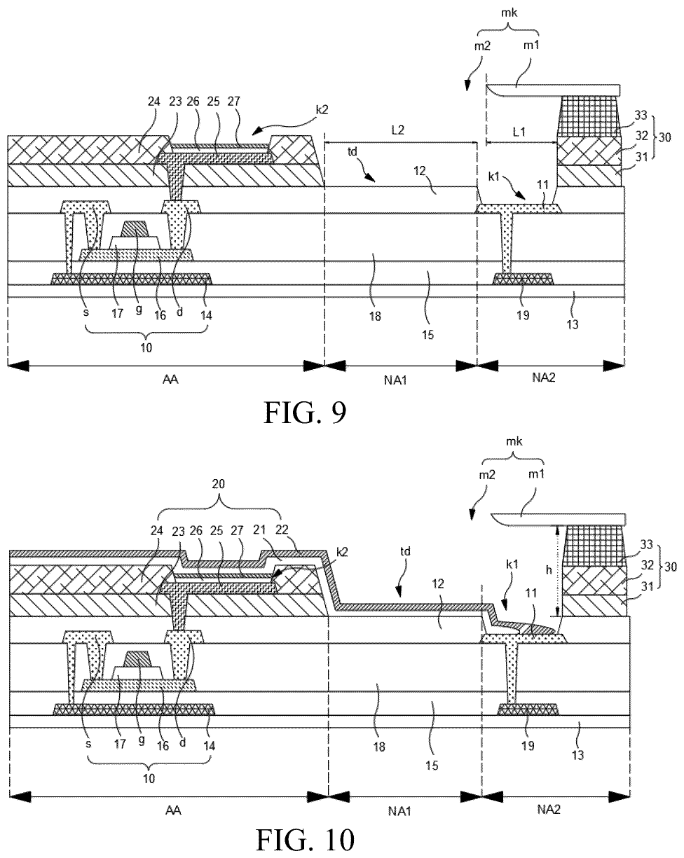

With reference to FIG. 9, a step B2, a mask mk is utilized to overlap the support member 30. The mask mk comprises a frame m1 and an aperture region m2. The frame m1 overlaps the support member 30. The display region AA and at least one portion of the buffer region NA1 are defined in a region in which the aperture region m2 is located. The frame m1 shields the at least region of the first aperture k1.

With reference to FIG. 10, a step B3 comprises by the same the mask mk for shielding, sequentially forming an electron functional layer 21 and a cathode 22 on the insulative lamination layer. A film formation range of the cathode 22 is greater than a film formation range of the electron functional layer 21. In the non-display region NA of an orthographic projection pattern of the display panel 100, a boundary of the cathode 22 extends beyond a boundary of the electron functional layer 21. The electron functional layer 21 at least covers the display region AA and the buffer region NA1. The cathode 22 covers the display region AA and the buffer region NA1 and is connected to the wiring 11 in the first aperture k1 through the channel td.

The display panel manufacturing method of the embodiment of the present application defines the channel td through the insulative lamination layer in the buffer region NA1 such that material of the cathode 22 can enter the cathode overlap region NA2 through the channel td and overlap the wiring 11 exposed by the first aperture k1.

It can be understood that when the electron functional layer 21 utilizes an evaporation process, the cathode 22 utilizes a sputtering process or an evaporation process with a smaller evaporation angle and form the electron functional layer 21 and the cathode 22 under the same mask mk. Because of the configuration of the channel td, material of the cathode 22 and the electron functional layer 21 can extend into the cathode overlap region NA2 through the channel td. Also, the cathode 22 utilizes the sputtering process or the smaller evaporation angle for evaporation such that the film formation range of the cathode 22 is greater than the film formation range of the electron functional layer 21 to make the cathode 22 able to overlap the wiring 11 to achieve light emission of the light emitting device layer 20, thereby lowering the manufacturing cost for the display panel 100.

The display panel manufacturing method will be described as follows.

In the step B1, an insulative lamination layer and a support member 30 is formed on the thin film transistor structure layer 10.

In particular, the step B1 comprises: sequentially forming a planarization layer 23, a first portion 31, an anode 25, a pixel definition layer 24, a second portion 32, and a third portion 33 on the thin film transistor structure layer 10. The planarization layer 23 and the pixel definition layer 24 constitute the insulative lamination layer. The first portion 31, the second portion 32, and the third portion 33 constitute the support member 30.

Optionally, the planarization layer 23 and the first portion 31 are made by the same mask. The pixel definition layer 24 and the second portion 32 are also made by the same mask. A second aperture k2 is defined in the pixel definition layer 24 to expose the anode 25.

After the step B1 and before the step B2, the method further comprises a step as follows: sequentially forming a hole functional layer 26 and a light emitting layer 27 in the second aperture k2. Then, the step B2 is implemented.

In the step B2, with reference to FIG. 9, a mask mk is used to overlap the support member 30.

Optionally, the mask mk comprises a frame m1 and the aperture region m2. The frame m1 overlaps the support member 30. A display region AA and at least one portion of the buffer region NA1 is disposed in a region in which the aperture region m2 is located. The frame m1 shields the at least region of the first aperture k1.

Optionally, the frame m1 can completely shield the first aperture k1 and can partially shield the first aperture k1.

Optionally, in an embodiment, the frame m1 partially shields the first aperture k1. The frame m1 shields ¼ to ¾ of an area of the first aperture k1. For example, the frame m1 shields ¼, ½, or ¾ of the area of the first aperture k1 to guarantee, in the later process, the electron functional layer 21 would not completely cover the first aperture k1, and the cathode 22 can directly overlap the wiring 11 in the first aperture k1.

Optionally, a distance L1 between an edge of the aperture region m2 and the support member 30 ranges from 100 nanometers to 500 nanometers, for example, the distance L1 can be 100 nanometers, 150 nanometers, 200 nanometers, 250 nanometers, 300 nanometers, 350 nanometers, 400 nanometers, 450 nanometers, or 500 nanometers.

It should be understood that if the edge distance of the aperture region m2 is too large, the more the frame m1 is suspended in the air, the more the part of the frame m1 near the aperture region m2 will deform and sag under the action of gravity, leading to a reduction in the distance between the frame m1 and the insulation layer 12. This affects the amount of material from the electron functional layer 21 and the cathode 22 entering the first aperture k1. Therefore, by setting the distance L1 from the edge of the aperture region m2 to the support member 30 from 100 nanometers to 500 nanometers, it can prevent the frame m1 from being excessively suspended, thereby preventing the edge of the aperture region m2 from deforming due to gravity. This reduces the risk of the frame m1 sagging and the risk of a reduction in the amount of cathode 22 material entering the first aperture k1.

Furthermore, when the cathode 22 utilizes an evaporation process in a later process, the evaporation angle for manufacturing the cathode 22 is θ. In the channel td region, the distance L2 between the first aperture k1 and the insulative lamination layer located in the display region AA is greater than or equal to the thickness h/tan θ of the support member 30 to guarantee that the material passes through the channel td.

For example, when an evaporation angle θ of the cathode 22 is 45 degrees, because h≥4 microns, the distance L2 is greater than or equal to 4 microns.

When the cathode 22 utilizes a sputtering process in a later process, to better cover the first aperture k1 with the cathode 22 material, the distance L2 between the first aperture k1 and the insulative lamination layer located in the display region AA is greater than or equal to 100 microns, for example, the distance L2 can be 100 microns, 110 microns, 120 microns, 130 microns, 140 microns, 150 microns, 160 microns, 170 microns, 180 microns, 190 microns, 200 microns, 250 microns, 300 microns, etc.

In the step B3, with reference to FIG. 10, by the mask mk for shielding, the electron functional layer 21 and the cathode 22 are formed sequentially on the insulative lamination layer.

Optionally, in an embodiment, an evaporation process is utilizes to form the electron functional layer 21 and the cathode 22. The evaporation angle for manufacturing the cathode 22 is less than an evaporation angle for manufacturing the electron functional layer 21, for example, the evaporation angle for manufacturing the cathode 22 is 45 degrees, and the evaporation angle for manufacturing the electron functional layer 21 is 90 degrees.

Because a position of the mask mk is not changed, under a circumstance of the evaporation angle for manufacturing the cathode 22 less than an evaporation angle for manufacturing the electron functional layer 21, the film formation range of the cathode 22 is greater than the film formation range of the electron functional layer 21.

Optionally, in an embodiment, an evaporation process is utilized to form the electron functional layer 21, and a sputtering process is utilized to form the cathode 22. Because during film formation of the sputtering process a sputtering direction of material particles is random, and during film formation of the evaporation process the material particles are limited by the evaporation angle, a film layer diffusion region of the film formation of the sputtering process would be greater than a film layer diffusion region of the film formation of the evaporation process when the same the mask mk is used for the film formation. Namely, the film layer covering region of the cathode 22 is greater than a film layer covering region of the electron functional layer 21 to make the cathode 22 able to directly overlap the wiring 11.

In other words, the display panel manufacturing method of the embodiment of the present application utilizes the mask mk to manufacture and form the electron functional layer 21 and the cathode 22 such that the cathode 22 can directly overlap the wiring 11 of the first aperture k1, thereby achieving an effect of saving process steps and process apparatuses to further lower the cost of the display panel 100.

The embodiment of the present application provides a display panel and a display panel manufacturing method, as described in detail above. Specific examples have been used to illustrate the principles and implementations of the present application. The explanation of the above embodiment is only intended to help understand the method and core ideas of the present application. At the same time, for those skilled in the art, there will be changes in the specific implementations and application ranges based on the ideas of the present application. Therefore, the content of this specification should not be construed as a limitation on the present application.

1. A display panel, comprising a display region and a non-display region located on at least one side of the display region, wherein the non-display region comprises a buffer region and a cathode overlap region located on a side of the buffer region away from the display region, and the display panel comprises:
a thin film transistor structure layer, wherein the thin film transistor structure layer comprises a wiring and an insulation layer covering the wiring, in the cathode overlap region, a first aperture is defined in the insulation layer, and the first aperture exposes the wiring;
a light emitting device layer, wherein the light emitting device layer is disposed on the thin film transistor structure layer, the light emitting device layer comprises an electron functional layer and a cathode covering the electron functional layer and located away from a side of the thin film transistor structure layer; and
a support member, wherein the support member is disposed on the insulation layer and is located on a side of the first aperture away from the buffer region;
wherein in the buffer region, at least one channel is defined in the light emitting device layer, and the channel extends along a direction toward the first aperture and communicates with the first aperture;
wherein in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel.

2. The display panel according to claim 1, wherein the support member is configured to support a mask; and
the cathode and the electron functional layer is configured to be formed by a same mask.

3. The display panel according to claim 1, wherein the light emitting device layer comprise a planarization layer covering the insulation layer and a pixel definition layer covering the planarization layer, and the electron functional layer covers the pixel definition layer; and
a surface of the insulation layer near the planarization layer serves as a datum surface, a height of a bottom surface of the channel is lower than is located on a surface of the pixel definition layer in the display region away from the thin film transistor structure layer, and the height of the bottom surface of the channel is higher or equal to the datum surface.

4. The display panel according to claim 3, wherein the channel extends through the planarization layer and the pixel definition layer.

5. The display panel according to claim 3, wherein the first aperture is at least one, in an orthographic projection pattern of the display panel, an extension direction of the channel intersects an extension direction of the wiring, and one of the at least one first aperture is disposed correspondingly on an extension direction of the at least one channel.

6. The display panel according to claim 3, wherein in an orthographic projection pattern of the display panel, and the support member is disposed and extends along an extension direction of the wiring.

7. The display panel according to claim 3, wherein a width of the support member is greater than or equal to 10 microns.

8. The display panel according to claim 3, wherein a thickness of the support member is greater than or equal to 4 microns.

9. The display panel according to claim 3, wherein at least one of the planarization layer and the pixel definition layer and at least one portion of the support member are disposed in a same layer and made of same material.

10. The display panel according to claim 9, wherein the support member comprises a first portion, a second portion, and a third portion sequentially stacked on the insulation layer, the first portion and the planarization layer are disposed in a same layer and made of same material, and the second portion and the pixel definition layer are disposed in a same layer and made of same material.

11. The display panel according to claim 1, wherein the electron functional layer is connected to a portion of the wiring in the first aperture through the channel, and the cathode covers the electron functional layer in the first aperture and is connected to an exposed portion of the wiring.

12. The display panel according to claim 3, wherein the electron functional layer comprises at least one of an electron transport layer and an electron injection layer, the light emitting device layer further comprises an anode, a light emitting layer, and a hole functional layer, the anode is disposed on the planarization layer, a second aperture is defined in the pixel definition layer, the second aperture exposes the anode, the hole functional layer and the light emitting layer are disposed sequentially on the anode and located in the second aperture, and the electron functional layer is disposed on the light emitting layer.

13. A display panel, comprising a display region and a non-display region located on at least one side of the display region, wherein the non-display region comprises a buffer region and a cathode overlap region located on a side of the buffer region away from the display region, and the display panel comprises:
a thin film transistor structure layer, wherein the thin film transistor structure layer comprises a wiring and an insulation layer covering the wiring, in the cathode overlap region, a first aperture is defined in the insulation layer, and the first aperture exposes the wiring;
a light emitting device layer, wherein the light emitting device layer is disposed on the thin film transistor structure layer, the light emitting device layer comprises an electron functional layer and a cathode covering the electron functional layer and located away from a side of the thin film transistor structure layer; and
a support member, wherein the support member is disposed on the insulation layer and is located on a side of the first aperture away from the buffer region;
wherein in the buffer region, at least one channel is defined in the light emitting device layer, and the channel extends along a direction toward the first aperture and communicates with the first aperture;
wherein in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel;
wherein the light emitting device layer comprise a planarization layer covering the insulation layer and a pixel definition layer covering the planarization layer, and the electron functional layer covers the pixel definition layer; and
wherein a surface of the insulation layer near the planarization layer serves as a datum surface, a height of a bottom surface of the channel is lower than is located on a surface of the pixel definition layer in the display region away from the thin film transistor structure layer, and the height of the bottom surface of the channel is higher or equal to the datum surface;
wherein the channel extends through the planarization layer and the pixel definition layer;
wherein the first aperture is at least one, in an orthographic projection pattern of the display panel, an extension direction of the channel intersects an extension direction of the wiring, and one of the at least one first aperture is disposed correspondingly on an extension direction of the at least one channel.

14. The display panel according to claim 13, wherein in an orthographic projection pattern of the display panel, and the support member is disposed and extends along an extension direction of the wiring.

15. The display panel according to claim 13, wherein a width of the support member is greater than or equal to 10 microns.

16. The display panel according to claim 13, wherein a thickness of the support member is greater than or equal to 4 microns.

17. The display panel according to claim 13, wherein at least one of the planarization layer and the pixel definition layer and at least one portion of the support member are disposed in a same layer and made of same material.

18. The display panel according to claim 17, wherein the support member comprises a first portion, a second portion, and a third portion sequentially stacked on the insulation layer, the first portion and the planarization layer are disposed in a same layer and made of same material, and the second portion and the pixel definition layer are disposed in a same layer and made of same material.

19. The display panel according to claim 13, wherein the electron functional layer is connected to a portion of the wiring in the first aperture through the channel, and the cathode covers the electron functional layer in the first aperture and is connected to an exposed portion of the wiring.

20. A display panel manufacturing method, wherein a display panel comprises a display region and a non-display region located on at least one side of the display region, wherein the non-display region comprises a buffer region and a cathode overlap region located on a side of the buffer region away from the display region, and the display panel manufacturing method comprises steps as follows:
form an insulative lamination layer and a support member on a thin film transistor structure layer, wherein the thin film transistor structure layer comprises a wiring and an insulation layer covering the wiring, in the cathode overlap region, a first aperture is defined in the insulation layer, and the first aperture exposes the wiring; the support member is disposed on the insulation layer and is located on a side of the first aperture away from the buffer region; at least one channel is formed in a region of the insulative lamination layer corresponding to the buffer region, and the first aperture is located along an extension direction of the channel;
overlapping a mask on the support member, wherein the mask comprises a frame and an aperture region, the frame overlaps the support member, the display region and at least one portion of the buffer region is disposed in a region in which the aperture region is located, and the frame shields at least one region of the first aperture; and
sequentially forming an electron functional layer and a cathode on the insulative lamination layer by the mask, wherein a film formation range of the cathode is greater than a film formation range of the electron functional layer, in the non-display region of an orthographic projection pattern of the display panel, a boundary of the cathode extends beyond a boundary of the electron functional layer, the electron functional layer at least covers the display region and the buffer region, and the cathode covers the display region and the buffer region and is connected to the wiring in the first aperture through the channel.
